(19) United States
(12) Patent Application Publication
(10) Pub. No.: US 2024/0332277 A1
(43) Pub. Date: Oct. 3, 2024

(54) SEMICONDUCTOR INTEGRATED CIRCUIT

(71) Applicant: ROHM CO., LTD., Kyoto (JP)

(72) Inventor: Hisashi SUGIE, Kyoto (JP)

(21) Appl. No.: 18/604,779

(22) Filed: Mar. 14, 2024

(30) Foreign Application Priority Data
Mar. 28, 2023 (JP) 2023-052370

(51) Int. Cl. H01L 27/01

(52) U.S. Cl. CPC H01L 27/01

(57) ABSTRACT

A semiconductor integrated circuit includes a first resistor formed on a semiconductor substrate, wherein the first resistor includes a first resistor element and a second resistor element, which are connected in series and have a same resistance value, and wherein a well in which the first resistor element is formed and a well in which the second resistor element is formed are connected to a connection node between the first resistor element and the second resistor element.

### CROSS-REFERENCE TO RELATED APPLICATIONS

The present invention claims priority under 35 U.S.C. § 119 to Japanese Application No. 2023-052370, filed on Mar. 28, 2023, the entire contents of which being incorporated herein by reference.

### TECHNICAL FIELD

The present disclosure relates to a resistor formed in a semiconductor integrated circuit.

### BACKGROUND

One of important components of a semiconductor integrated circuit is a resistor. There are various types of resistors. A poly resistor, a diffused resistor, a metal resistor, or the like is used according to applications thereof.

A resistance value of a resistor formed on a semiconductor substrate changes slightly according to a voltage applied thereto. This is called voltage modulation. The voltage modulation is not a problem in many applications because it is on the order of 0.1% or less at most even when applying a large voltage in excess of 10 V.

### BRIEF DESCRIPTION OF DRAWINGS

The accompanying drawings, which are incorporated in and constitute a part of the specification, illustrate embodiments of the present disclosure.

FIG. 1 is a cross-sectional view of a semiconductor integrated circuit including a resistor according to one embodiment.

FIG. 2 is a cross-sectional view of a semiconductor integrated circuit including a resistor according to a comparative technique.

FIG. 3 is a view showing a result of a simulation on resistance values of the resistor according to the embodiment and the resistor according to the comparison technique.

FIG. 4A to FIG. 4C are circuit diagrams used in the simulation of FIG. 3.

FIG. 5 is a cross-sectional view of a semiconductor integrated circuit including a resistor according to a modification.

FIG. 6 is a circuit diagram of an amplifier circuit according to one embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Summary of Embodiments

A summary of some exemplary embodiments of the present disclosure will be described. This summary is intended to provide a simplified description of some concepts of one or more embodiments in order to provide a basic understanding of the embodiments as a prelude to the following detailed description and is not intended to limit the scope of the invention or the disclosure. This summary is not an exhaustive overview of all conceivable embodiments and is not intended to identify key elements of all embodiments or to delineate the scope of any or all embodiments. For the sake of convenience, “one embodiment” may be used to refer to one embodiment (example or modification) or multiple embodiments (examples or modifications) disclosed in this specification.

A semiconductor integrated circuit according to one embodiment includes a resistor formed on a semiconductor substrate. The resistor includes a first resistor element and a second resistor element connected in series and having an equal resistance value. A well in which the first resistor element is formed and a well in which the second resistor element is formed are connected to a connection node between the first resistor element and the second resistor element.

According to this configuration, since one resistor is divided into two resistor elements and a voltage corresponding to a midpoint voltage is applied to the well of each resistor element, it is possible to reduce the influence of voltage modulation.

In one embodiment, the well in which the first resistor element is formed and the well in which the second resistor element is formed may be the same well.

In one embodiment, the well in which the first resistor element is formed and the well in which the second resistor element is formed may be independent wells.

In one embodiment, the first resistor element and the second resistor element may be poly resistors.

In one embodiment, the first resistor element and the second resistor element may be diffused resistors.

In one embodiment, the semiconductor integrated circuit may further include a subtraction amplifier circuit including an operational amplifier. A resistor of the subtraction amplifier circuit may be configured using the resistor of the above configuration.

In one embodiment, the semiconductor integrated circuit may further include a non-inverting amplifier including an operational amplifier. A resistor of the non-inverting amplifier may be configured using the resistor of the above configuration.

In one embodiment, the semiconductor integrated circuit may further include an inverting amplifier including an operational amplifier. A resistor of the inverting amplifier may be configured using the resistor of the above configuration.

### Embodiment

Hereinafter, preferred embodiments will be described with reference to the drawings. Identical or equivalent components, members, and processes shown in each drawing are designated by like reference numerals, and redundant explanations thereof will be omitted as appropriate. Further, the embodiments are exemplary rather than limiting the disclosure and the invention. All features and combinations thereof described in the embodiments are not necessarily essential to the disclosure and the invention.

In the present disclosure, “a state where a member A is connected to a member B” includes a case where the member A and the member B are physically and directly connected or even a case where the member A and the member B are indirectly connected via any other member that does not affect an electrical connection state between the members A and B or does not impair functions and effects achieved by combinations of the members A and B.

Similarly, “a state where a member C is installed between a member A and a member B” includes a case where the member A and the member C or the member B and the member C are indirectly connected via any other member that does not affect an electrical connection state between the members A and C or the members B and C or does not impair functions and effects achieved by combinations of the members A and C or the members B and C, in addition to a case where the member A and the member C or the member B and the member C are directly connected.

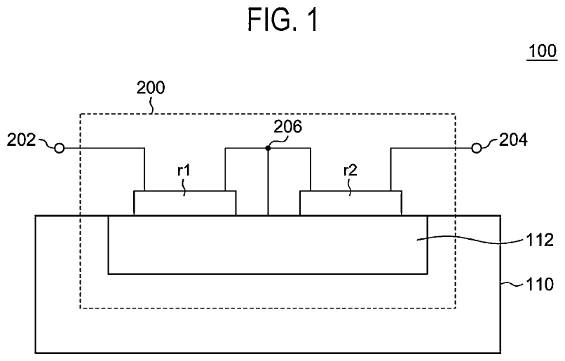

FIG. 1 is a cross-sectional view of a semiconductor integrated circuit 100 including a resistor 200 according to one embodiment. The resistor 200 is formed on a semiconductor substrate 110. The resistor 200 has a first end 202 and a second end 204.

A well 112 is formed in the semiconductor substrate 110. The resistor 200 is formed over the well 112. The resistor 200 is divided into a first resistor element r1 and a second resistor element r2 connected in series between the first end 202 and the second end 204. Assuming that a design value of a resistance value of the resistor 200 is r, the first resistor element r1 and the second resistor element r2 are designed so that respective resistance values thereof are equal to r/2. The first resistor element r1 and the second resistor element r2 are poly resistors or diffused resistors.

A voltage corresponding to a midpoint voltage between a voltage at the first end 202 and a voltage at the second end 204 is applied to the well 112. Specifically, the well 112 is connected to a connection node 206 between the first resistor element r1 and the second resistor element r2.

The above is a configuration of the resistor 200. Advantages of the resistor 200 will become apparent when compared with a comparative technique. Therefore, the comparative technique will be described first.

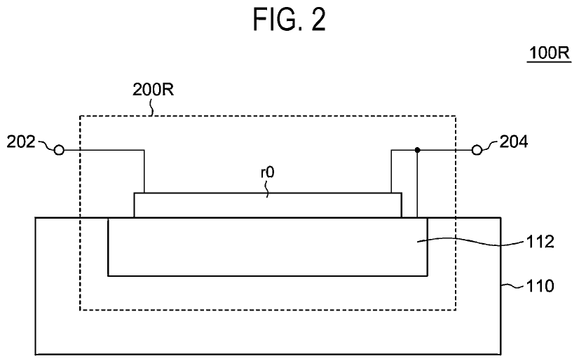

FIG. 2 is a cross-sectional view of a semiconductor integrated circuit 100R including a resistor 200R according to a comparative technique. The resistor 200R includes a single resistor element r0, which is formed on a well 112 and has a resistance value of r. The well 112 is connected to one of the first end 202 and the second end 204 (here, the second end 204). The above is a configuration of the resistor 200R.

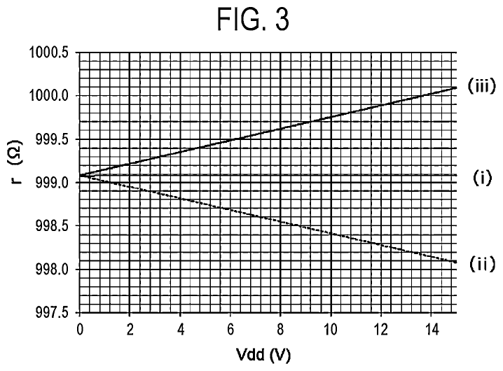

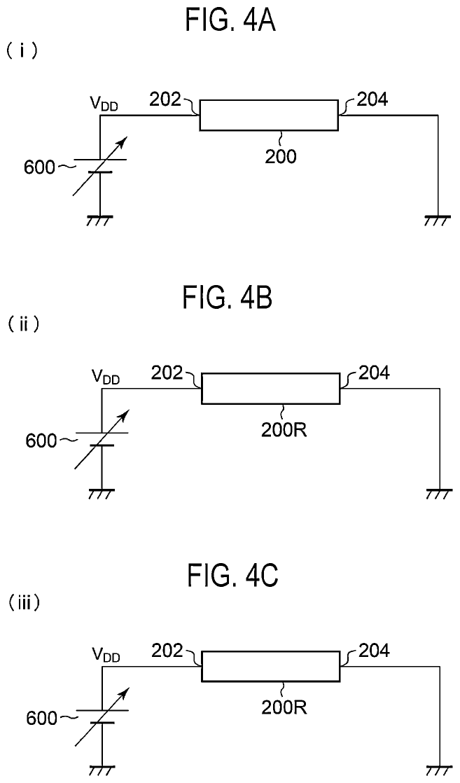

FIG. 3 is a view showing a result of a simulation on resistance values of the resistor 200 according to the embodiment and the resistor 200R according to the comparative technique. FIGS. 4A to 4C are circuit diagrams used in the simulation of FIG. 3. The design values of the resistors 200 and 200R are 1 kilo-ohms. In circuit (i), the second end 204 of the resistor 200 was grounded, and the first end 202 was connected to a variable voltage source 600 (see FIG. 4A). In circuit (ii), the second end 204 of the resistor 200R was grounded, and the first end 202 was connected to the variable voltage source 600 (see FIG. 4B). In circuit (iii), the first end 202 of the resistor 200R was grounded, and the second end 204 was connected to the variable voltage source 600 (see FIG. 4C). A voltage V_{DD} of the variable voltage source 600 was swept from 0 V to 10 V, a current flowing through the resistor was measured, and a resistance value was calculated from the voltage and the current.

As shown in FIG. 3, in the circuits (ii) and (iii) using the resistor 200R according to the comparative technique, the resistance value r changed according to the power supply voltage V_{DD}, and an effect of voltage modulation appeared. On the other hand, in the circuit (i) using the resistor 200 according to the embodiment, the resistance value r showed a constant value regardless of the power supply voltage V_{DD}, indicating that the effect of voltage modulation can be suppressed.

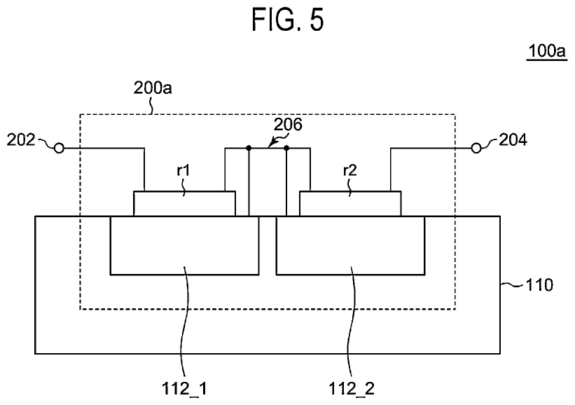

FIG. 5 is a cross-sectional view of a semiconductor integrated circuit 100a including a resistor 200a according to a modification. In this modification, the first resistor element r1 and the second resistor element r2 are formed separately on independent wells 112_1 and 112_2, respectively. The wells 112_1 and 112_2 are connected to the connection node 206 between the first resistor element r1 and the second resistor element r2. With this configuration also, the effect of voltage modulation can be suppressed as in the resistor 200 shown in FIG. 1. However, since the wells 112_1 and 112_2 are independent in this modification, a circuit area is larger than that of the resistor 200 shown in FIG. 1.

Next, an application of the resistor 200 will be described. The resistor 200 can be appropriately used in a circuit that requires high accuracy on the order of 0.1%. For example, an appropriate application of the resistor 200 is an amplifier circuit which is a combination of an operational amplifier and a resistor.

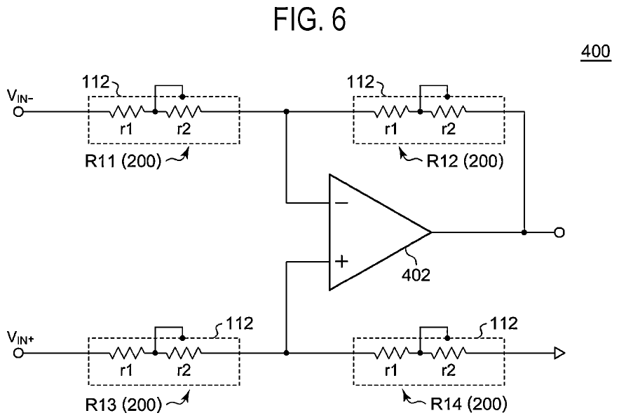

FIG. 6 is a circuit diagram of an amplifier circuit 400 according to one embodiment. The amplifier circuit 400 is a subtraction amplifier including an operational amplifier 402 and resistors R11 to R14. Since R11=R13 and R12-R14, a gain of the amplifier circuit 400 is g=R13/R11. The resistors R11 to R14 are the resistor 200 shown in FIG. 1.

The amplifier circuit is not limited to the subtraction amplifier but may be a non-inverting amplifier or an inverting amplifier.

Other applications of the resistor 200 include an A/D converter and a D/A converter. Alternatively, the resistor 200 may be used in a resistor voltage divider circuit used for voltage detection means such as an under voltage lock out (UVLO) circuit, an over voltage protection (OVP) circuit, or the like.

### (Supplementary Notes)

The following technique is disclosed in this specification.

### (Item 1)

A semiconductor integrated circuit, comprising a first resistor formed on a semiconductor substrate,
wherein the first resistor includes a first resistor element and a second resistor element, which are connected in series and have a same resistance value, and
wherein a well in which the first resistor element is formed and a well in which the second resistor element is formed are connected to a connection node between the first resistor element and the second resistor element.

### (Item 2)

The semiconductor integrated circuit of Item 1, wherein the well in which the first resistor element is formed and the well in which the second resistor element is formed are a same well.

### (Item 3)

The semiconductor integrated circuit of Item 1, wherein the well in which the first resistor element is formed and the well in which the second resistor element is formed are independent wells.

### (Item 4)

The semiconductor integrated circuit of any one of Items 1 to 3, wherein the first resistor element and the second resistor element are poly resistors.

### (Item 5)

The semiconductor integrated circuit of any one of Items 1 to 3, wherein the first resistor element and the second resistor element are diffused resistors.

### (Item 6)

The semiconductor integrated circuit of any one of Items 1 to 5, further comprising an amplifier circuit including an operational amplifier and a resistor,
wherein the resistor of the amplifier circuit is configured using the first resistor.

While certain embodiments have been described, these embodiments have been presented by way of example only and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor integrated circuit, comprising a first resistor formed on a semiconductor substrate,
wherein the first resistor includes a first resistor element and a second resistor element, which are connected in series and have a same resistance value, and
wherein a well in which the first resistor element is formed and a well in which the second resistor element is formed are connected to a connection node between the first resistor element and the second resistor element.

2. The semiconductor integrated circuit of claim 1, wherein the well in which the first resistor element is formed and the well in which the second resistor element is formed are a same well.

3. The semiconductor integrated circuit of claim 1, wherein the well in which the first resistor element is formed and the well in which the second resistor element is formed are independent wells.

4. The semiconductor integrated circuit of claim 1, wherein the first resistor element and the second resistor element are poly resistors.

5. The semiconductor integrated circuit of claim 1, wherein the first resistor element and the second resistor element are diffused resistors.

6. The semiconductor integrated circuit of claim 1, further comprising an amplifier circuit including an operational amplifier and a resistor,
wherein the resistor of the amplifier circuit is configured using the first resistor.
